(19) United States
(12) Patent Application Publication
(10) Pub. No.: US 2015/0179910 A1
(43) Pub. Date: Jun. 25, 2015

(54) System For Converting Thermal Energy Into Electrical Energy

(71) Applicant: United Arab Emirates University, Al-Ain (AE)

(72) Inventors: Yosef Al Jasem, Al-Ain (AE); Thies Thiemann, Al-Ain (AE)

(73) Assignee: United Arab Emirates University, Al-Ain (AE)

(21) Appl. No.: 14/139,292

(22) Filed: Dec. 23, 2013

(51) Int. Cl. H01L 35/30

(52) U.S. Cl. CPC H01L 35/30

(57) ABSTRACT

A system is configured to convert thermal energy into electrical energy, the system comprising a solar concentrator for directing sunlight to a portion of heat transfer fluid; said portion of heat transfer fluid being for absorbing solar energy from the sunlight and converting the solar energy into thermal energy; and a conveyance for transferring the portion of heat transfer fluid; the thermoelectric generator is configured to generate electrical energy via the thermoelectric effect; wherein the system is configured such that the thermoelectric generator is submerged in water and is configured to generate electrical energy based on a temperature difference caused by the heat transfer fluid and the water.

### TECHNICAL FIELD

This invention generally relates to a system and method for energy conversion, and in particular to a system and method for converting solar energy into thermal energy and subsequently into electrical energy by the thermoelectric effect.

### BACKGROUND ART

Thermoelectric generators are devices that convert thermal energy into electrical energy as a result of the thermoelectric effect which takes advantage of temperature differences to convert thermal energy into electrical voltage (and vice versa).

U.S. Pat. No. 3,023,257 describes a thermoelectric generation system which uses thermal energy in the form of solar radiation to generate electric energy. This system comprises multiple thermoelectric elements and parabolic reflectors which are configured to focus solar energy. Electricity is generated as there is a temperature difference across the thermoelectric elements.

U.S. Pat. No. 4,276,440 describes a thermoelectric generator which utilises solar energy and other sources of heat, in combination with a cooling device.

US 2009/0229650 describes a solid state thermoelectric generator which utilises thermal energy collected from solar radiation. This generator is able to directly drive a high voltage grid without the need for a step-up transformer.

US 2010/0288323 describes a thermoelectric generator system comprising a solar collector, a heat storage medium, transfer media and a thermoelectric generator.

US 2010/0300504 describes a system for electricity generation using a thermoelectric generator, cooling element and a solar power collector panel.

U.S. Pat. No. 4,397,300 describes a closed loop solar collector consisting of a parabolic solar concentrator with a linear vaporiser aligned along the parabolic reflector's focal line, vaporizable heat transfer fluid supplied from a storage tank and a heat exchanger.

US 2010/0186794 describes a solar thermoelectric and thermal cogeneration system which consists of a solar radiation absorber, thermoelectric generators and a solid fluid heating or a solar thermal to electric conversion plant.

### DISCLOSURE OF THE INVENTION

A first aspect of the invention provides a system for converting thermal energy into electrical energy comprising a solar concentrator for directing sunlight to a portion of heat transfer fluid; said portion of heat transfer fluid being for absorbing solar energy from the sunlight and converting the solar energy into thermal energy; and a conveyance for transferring the portion of heat transfer fluid towards a thermoelectric generator; the thermoelectric generator is configured to generate electrical energy via the thermoelectric effect; wherein the system is configured such that the thermoelectric generator is submerged in water and is configured to generate electrical energy based on a temperature difference between the portion of heat transfer fluid and the water.

Preferably the thermoelectric generator is positioned below the surface of the water and it is submerged in and wherein the water is contained in a reservoir.

Preferably the system further comprises a feedback loop for recycling said portion of heat transfer fluid from the thermoelectric generator back to absorb further solar energy from sunlight directed by the solar concentrator.

Preferably the feedback loop comprises a storage tank.

In one embodiment the solar concentrator is located on shore.

In an alternative embodiment the solar concentrator is located off shore.

In a further embodiment the system is located on an artificial island buoyant on the surface of the water.

Preferably the thermoelectric generator comprises one or more panels arranged to be joined together such that the outer facing surfaces of the one or more panels incorporate one or more thermoelectric modules which interface the water and the inner facing surfaces form a duct for conveying liquid heat transfer fluid received from the conveyance.

Preferably one or more panels are joined to form a duct with a cross-sectional area which is substantially circular, triangular or rectangular.

Preferably an array of fins are formed on and substantially perpendicular to the outer surface of each panel.

In a preferred embodiment the solar concentrator is configured to automatically alter its orientation according to the position of the sun at that time of day to maximise the amount of sunlight being directed to the heat transfer fluid at that time of day.

Preferably the artificial island is capable of rotating to a direction according to the sun's position to maximise the amount of solar radiation captured by the solar concentrators.

A second aspect of the invention provides a system for converting thermal energy into electrical energy comprising: a solar concentrator for directing sunlight to a portion of heat transfer fluid; said portion of heat transfer fluid being for absorbing solar energy from the sunlight and converting the solar energy into thermal energy; a first conveyance for transferring the portion of heat transfer fluid towards a steam generator for converting water into steam; and a second conveyance for conveying the steam to a thermoelectric generator for converting thermal energy into electrical energy by the thermoelectric effect; wherein the thermoelectric generator is submerged in water and is configured to generate electrical energy based on a temperature difference between the steam and the surrounding water. the second conveyance is configured to recycle the steam back to the steam generator via a condensation unit for condensing the steam into water.

Preferably, the system further comprises a steam driven turbine for generating electrical energy using the generated steam.

Preferably, the system further comprises a third conveyance for conveying the heat transfer fluid to a heat exchanger for storing heat from the heat transfer fluid using molten salt.

A third aspect of the invention provides method of converting thermal energy into electrical energy said method comprising: directing sunlight, by a solar concentrator, to a portion of heat transfer fluid; converting, by the heat transfer fluid, solar energy absorbed from the sunlight to thermal energy; conveying the portion of heat transfer fluid; and converting, by the thermoelectric generator, thermal energy into electrical energy via the thermoelectric effect; wherein the method further comprises submerging the thermoelectric generator in water, and wherein said electrical energy is generated based on a temperature difference between the portion of heat transfer fluid and the water or based on a temperature difference between steam and the surrounding water, wherein the steam is generated by water heated by the heat transfer fluid.

Preferably the method further comprises recycling the portion of heat transfer fluid from the thermoelectric generator back to absorb further solar energy directed by the solar concentrator.

Preferably the method further comprises adjusting the orientation of the solar concentrator such that the amount of sunlight being reflected is optimised for the position of the sun at that time of day.

Preferably the method further comprises conveying the portion of heat transfer fluid through one or more additional solar concentrators before conveying it towards the thermoelectric generator.

### BRIEF DESCRIPTION OF THE DRAWINGS

The invention will now be described by way of example with reference to the accompanying drawings:

FIG. 1 shows a perspective view of a system of a first embodiment of the present invention where the solar concentrators are located on shore;

FIG. 2 shows a perspective view of a system of a second embodiment of the present invention where the solar concentrators are located off shore;

FIG. 2a shows a side view the system of the second embodiment of the present invention where the solar concentrators are located off shore;

FIG. 3 shows a system according to a third embodiment of the present invention located on an artificial island buoyant on the surface of the water;

FIG. 4 shows a side view of solar concentrator used in various embodiment of the present invention;

FIG. 5 shows a side view of a thermoelectric generator with three panels joined together to form a triangular cross-sectional area;

FIG. 6 shows a cut away view of a thermoelectric generator with three panels joined together to form a triangular cross-sectional area;

FIG. 7 shows an end view of an inner duct of a thermoelectric generator according to one embodiment of the present invention, the inner duct shown in this figure has a triangular cross-sectional area;

FIG. 8 shows an end view of an outer duct of a thermoelectric generator according to one embodiment of the present invention, the outer ducts shown in this figure has a triangular cross-sectional area;

FIG. 9 shows an end view of an outer duct of a thermoelectric generator according to one embodiment of the present invention, the outer ducts shown in this figure has a triangular cross sectional area;

FIG. 10 shows a cross-sectional view of the thermoelectric generator shown in FIG. 6;

FIG. 11 shows a thermoelectric generator according to one embodiment of the present invention with four panels joined together to form a rectangular cross-sectional area;

FIG. 12 shows a thermoelectric generator according to one embodiment of the present invention with one panel joined to form a duct with a circular cross-sectional area; and

FIG. 13 shows an embodiment of the invention incorporating a steam generator with a conveyance for recycling the steam back to the steam generator.

### MODE(S) FOR CARRYING OUT THE INVENTION

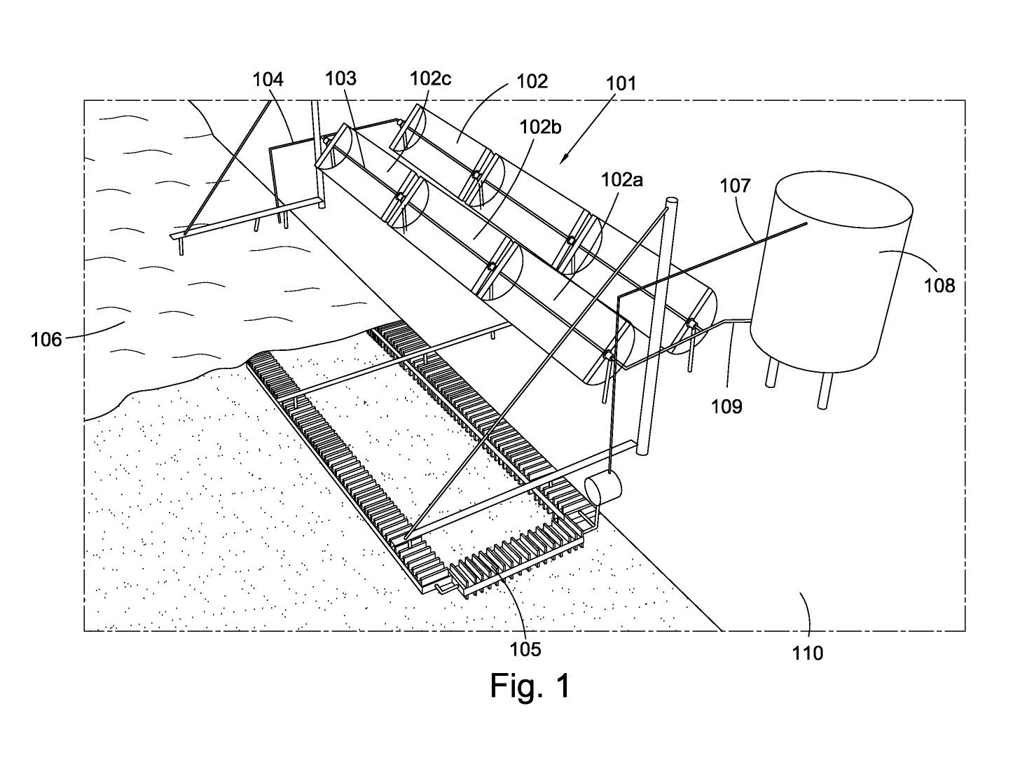

FIG. 1 shows an embodiment of the present invention comprising a system (101) for converting thermal energy into electrical energy comprising a solar concentrator (102) for directing sunlight to a portion of heat transfer fluid (103); said portion of heat transfer fluid being for absorbing solar energy from the sunlight and converting the solar energy into thermal energy. The system also comprises a conveyance (104) for transferring the portion of heat transfer fluid towards a thermoelectric generator (105). The thermoelectric generator is configured to generate electrical energy via the thermoelectric effect; wherein the system is configured such that the thermoelectric generator is submerged in water (106) and is configured to generate electrical energy based on a temperature difference between the portion of the heated heat transfer fluid and the water.

This invention also provides a method of converting thermal energy into electrical energy said method comprising: directing sunlight, by a solar concentrator, to a portion of heat transfer fluid; converting, by the heat transfer fluid, solar energy absorbed from the sunlight to thermal energy; conveying the portion of heat transfer fluid towards a thermoelectric generator; and converting, by the thermoelectric generator, thermal energy into electrical energy via the thermoelectric effect; wherein the method further comprises submerging the thermoelectric generator in water, and wherein said electrical energy is generated based on a temperature difference between the portion of heat transfer fluid and the water.

The thermoelectric generator may be positioned below the surface of the water it is submerged in and wherein the water is contained in a reservoir which may be a natural water source, such as a sea or lake, or a man made water source.

The system includes a conveyance for transferring a portion of the heat transfer fluid towards the solar concentrator. Preferably the length of the conveyance is as short as possible in order to minimise heat loss. The conveyance may also be contained within insulating material to reduce heat loss.

The system may also be configured such that one or more solar concentrators are arranged to allow the portion of heat transfer fluid to be transferred from the first solar concentrator, through each subsequent solar concentrator before being transferred towards the thermoelectric generator. The embodiment of the invention shown in FIG. 1 has six solar concentrators, with three solar concentrators arranged in two rows. The solar concentrators have reflection panels preferably in a parabolic shape for focusing the sunlight towards a focal line where the conveyance (104) conducting the heat transfer fluid is positioned to heat up the fluid passing through. In operation the portion of heat transfer fluid flows from the first solar concentrator (102a) in the first row, through the second and third solar concentrators (102b, 102c) in the first row before being transferred towards the thermoelectric generator (105) via the conveyance (104). Similarly the method may also involve conveying the portion of heat transfer fluid through one or more additional solar concentrators before conveying it towards the thermoelectric generator (105). Thermoelectric generator is submerged in water (106) and is configured to generate electrical energy based on a temperature difference between the portion of the heated heat transfer fluid flowing within a duct of the thermoelectric generator and the water surrounding an outer of the surface of the thermoelectric generator. The fluid flowing within the duct has a higher temperature due to absorption of solar energy than the water outside the duct. The generated electricity is transmitted to devices using it and/or to a power network which is capable of distributing it across a large area.

The system may also include a feedback loop (107) for recycling the fluid from the thermoelectric generator (105) back to the solar concentrators to absorb further solar energy from sunlight directed by the solar concentrator. Preferably this is achieved by pumping the heat transfer fluid in the thermoelectric generator back to the solar generator to repeat the cycle.

The feedback loop may incorporate a storage container (108). Heat transfer fluid is stored in the storage tank before it flows out towards the first solar concentrator. The heat transfer fluid flow rate is controlled by a control valve (109) which is located between the storage tank and the first solar concentrator and ideally directly after the storage tank.

The embodiment shown in FIG. 1 is the embodiment of the invention where the solar concentrators are located on shore on a body of land (110). Given that in a preferred embodiment of the invention the conveyance between the solar converter and the thermoelectric generator is shortened to minimise heat loss it is preferred that the solar concentrators are constructed on shore to be as close to the water as possible.

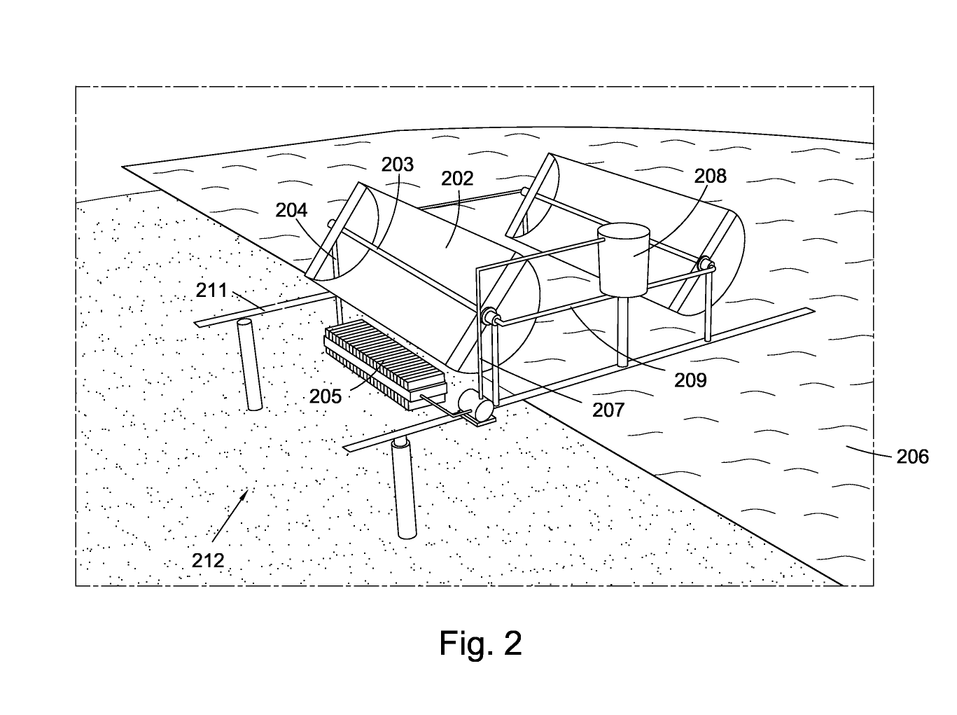

FIGS. 2 and 2a show embodiments of the present invention where the solar concentrators are located off shore. Here the solar concentrators may be positioned on an installation (211) which should ideally be anchored to the sea floor (212). The storage tank (208) may also be positioned on the installation (211). The installation supports the solar concentrators and the storage tank such that they are above the water surface. In order to minimise the length of the conveyance between the solar concentrator and the thermoelectric generator the height of the installation should be set such that the solar concentrators are positioned just above the water level. As the depth of the water varies, i.e. due to tidal fluctuations, the installation may also be capable of extending and retracting along its vertical axes such that the solar concentrators are always positioned just above the water level. The operation of the system of this embodiment is similar to that of the embodiment shown in FIG. 1: the solar concentrators focus sunlight towards a focal line where the conveyance (204) conducting the heat transfer fluid is positioned; the heated fluid is conveyed to the thermoelectric generator submerged in water (206) which is configured to generate electrical energy based on a temperature difference between the heated heat transfer fluid flowing within the thermoelectric generator and the water surrounding the thermoelectric generator. A pump pumps the fluid from the thermoelectric generator back to the storage tank before the fluid is circulated back to the solar generators.

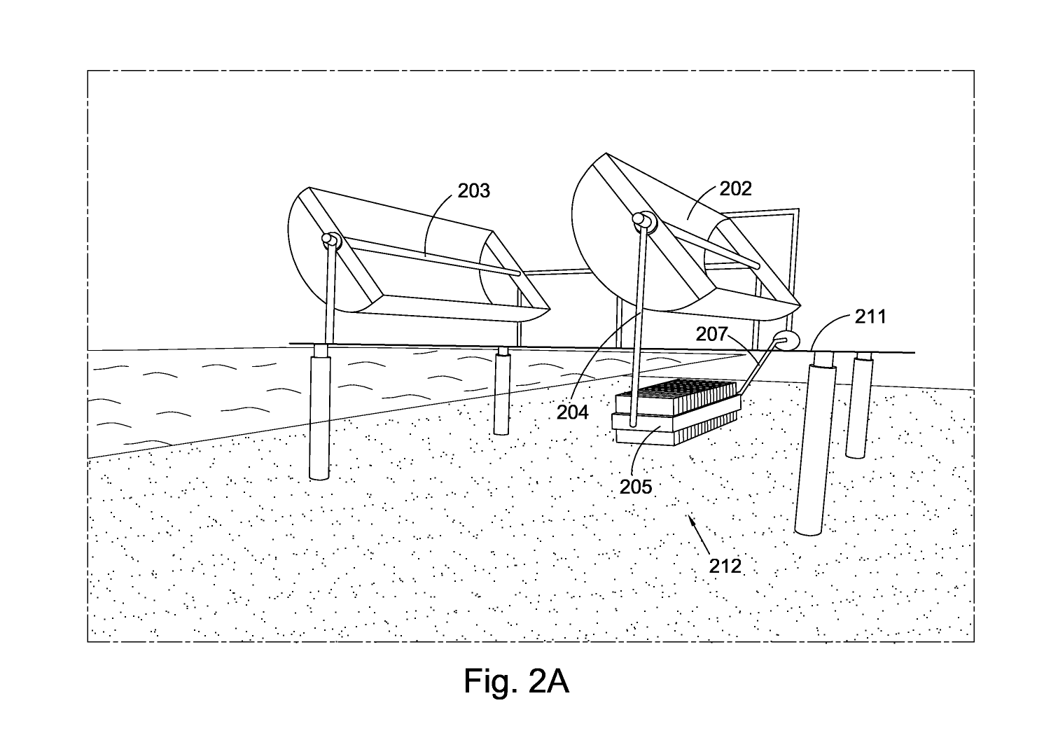

FIG. 3 shows an embodiment of the invention where the system is located on an artificial island (313) buoyant on the surface of the water. The artificial island may be detached from the bottom of the reservoir or may be anchored to the bottom of the water reservoir. The artificial island is ideally constructed from a buoyant ring (314), which can be either substantially circular or substantially rectangular. The buoyant ring holds the island just above the surface of the water. A platform (315) is formed in the area within the buoyant ring with the one or more solar concentrators being positioned on the upper surface of this platform. Where multiple solar concentrators are incorporated, they are preferably evenly distributed across the platform and/or are positioned towards the middle of the platform to ensure that the island is properly balanced. The embodiment of the invention shown in FIG. 3 also incorporates a feedback loop and a storage tank which is also positioned on the upper surface of the horizontal platform.

Thermoelectric generators are held below the surface of the water by holders (316) attached to the bottom surface of the platform. The holders are capable of being axially extended and retracted so that their lengths are capable of being varied according to requirements. The electricity generated by the thermoelectric generators can be transferred from the system via electrical wiring (317).

In the embodiment shown in FIG. 3, an array of solar concentrators are arranged in parallel rows with the conveyance running through each solar concentrator in the series and snaking back and forth along each of the rows. The thermoelectric generator comprises an array of thermoelectric generator units arranged in series snaking back and forth in rows as can be seen in the cut away portion of FIG. 3. In operation the heat transfer fluid flows along the conveyance through the focal line of each solar concentrator in the direction indicated by the arrows. When the heat transfer fluid reaches the final solar concentrator in the series it is transferred to the first thermoelectric generator unit in the series as the conveyance penetrates through the platform. The heat transfer fluid flows through each thermoelectric generator unit in turn, in the direction indicated by the arrows, before being recycled back via the feedback loop and storage tank to the first solar concentrator. Alternatively, the connection of lines of thermoelectric generators may be parallel instead of series. Likewise, the arrays of solar concentrators may be connected in parallel or in a mixture of parallel arrangement and series arrangement.

In embodiments of the invention where the system is located on an artificial island it is possible to have both moving and non-moving configurations of this embodiment. For a non-moving configuration the artificial island does not substantially change its position or its direction. A moving artificial island however is capable of rotating in order to maximise the amount of solar radiation captured by the solar concentrators according to the sun's position. A moving island is the preferred configuration in areas of the world at high latitude as the island is capable of rotating to track the sun's position and motion. Artificial islands which are substantially circular are the preferred configuration for a moving island as mechanically these are easier to rotate.

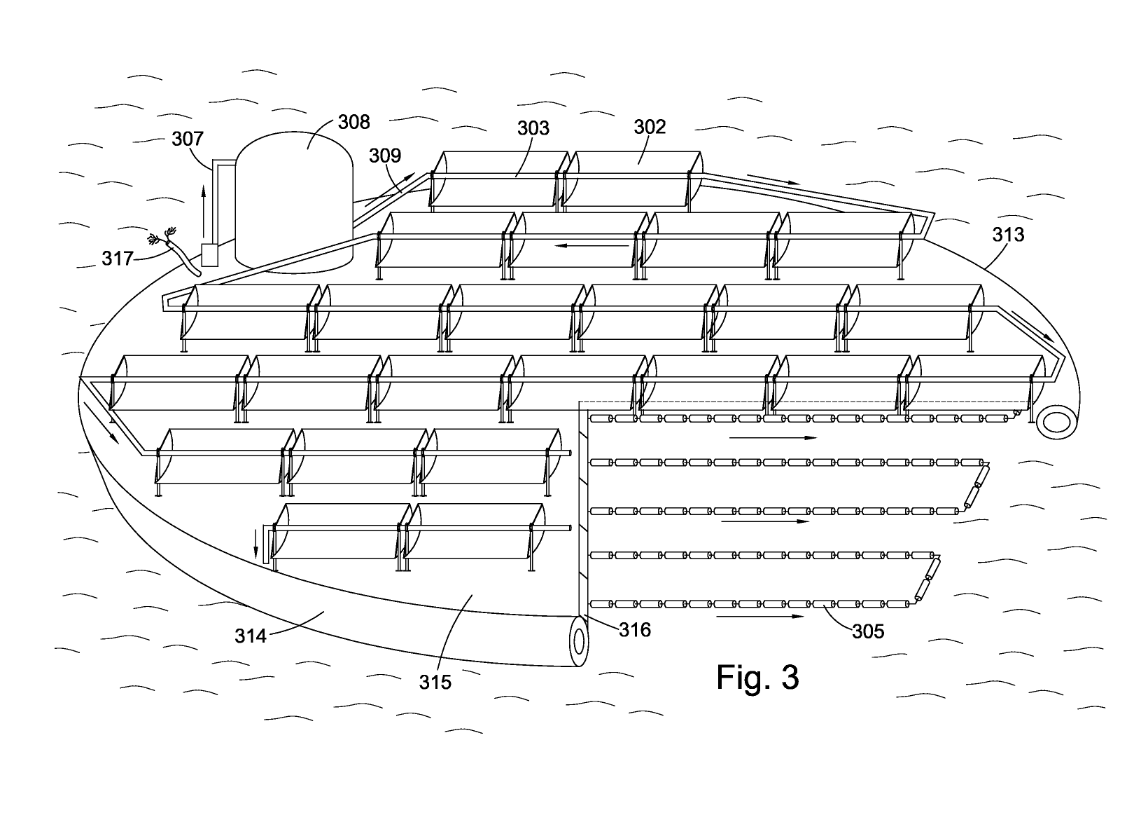

FIG. 4 shows a parabolic solar concentrator. Parabolic solar concentrators are the preferable construct for directing an optimal amount of solar irradiation towards the focal line of the parabolic solar concentrator where the heat transfer fluid is located.

At the focal point of each solar concentrator vacuum tubing assembly (418) is provided comprising two tubes (419, 420). In operation heat transfer fluid flows through the inner metal tube (419) which is surrounded by outer glass tubing (420). The annulus space between the outer in inner tubing is filled with low thermal and electrical conductivity gas such as argon. Ideally the vacuum tubing is elongate and set along the focal line of the solar concentrator in order to optimise the amount of solar energy being absorbed by the heat transfer fluid passing through.

Preferably the method additionally includes adjusting the orientation of the solar concentrator such that the amount of sunlight being reflected is optimised for the position of the sun at that time of day and the solar concentrator is configured to be able to do this automatically. The solar concentrators are directed towards the sun by using a precise tracking system, for example tracking motors (421) controlled by a controller, such as a computer or a electronic circuit comprising at least one processor and one memory.

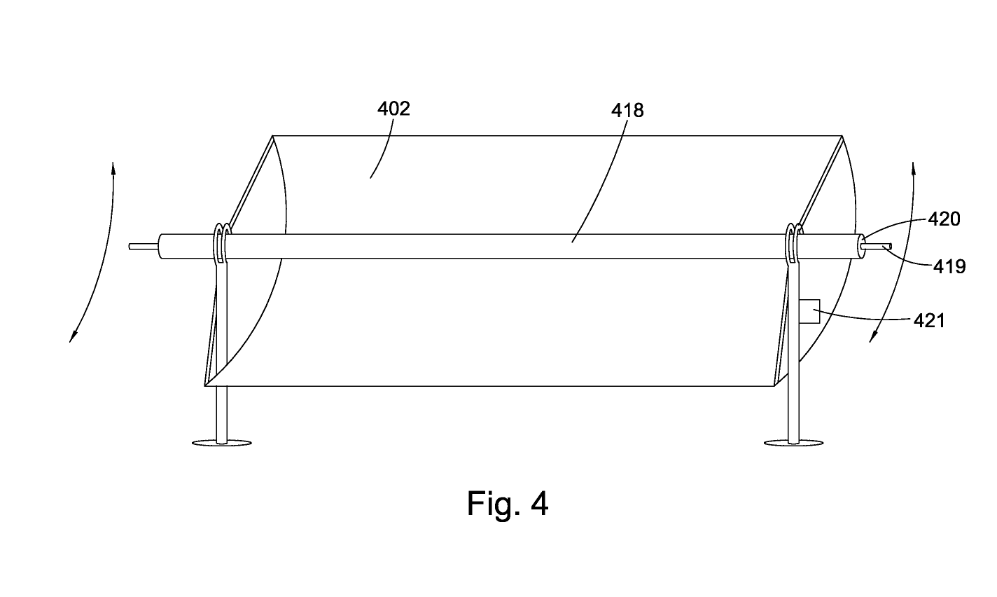

FIGS. 5 to 12 show different views and embodiments of the thermoelectric generators. The thermoelectric generator may comprise one or more panels (522, 622) arranged to be joined together such that the outer facing surfaces of the one or more panels incorporate one or more thermoelectric modules (523, 623) which interface the water and the inner facing surfaces of the panels to form a duct for conveying heat transfer fluid received from the conveyance.

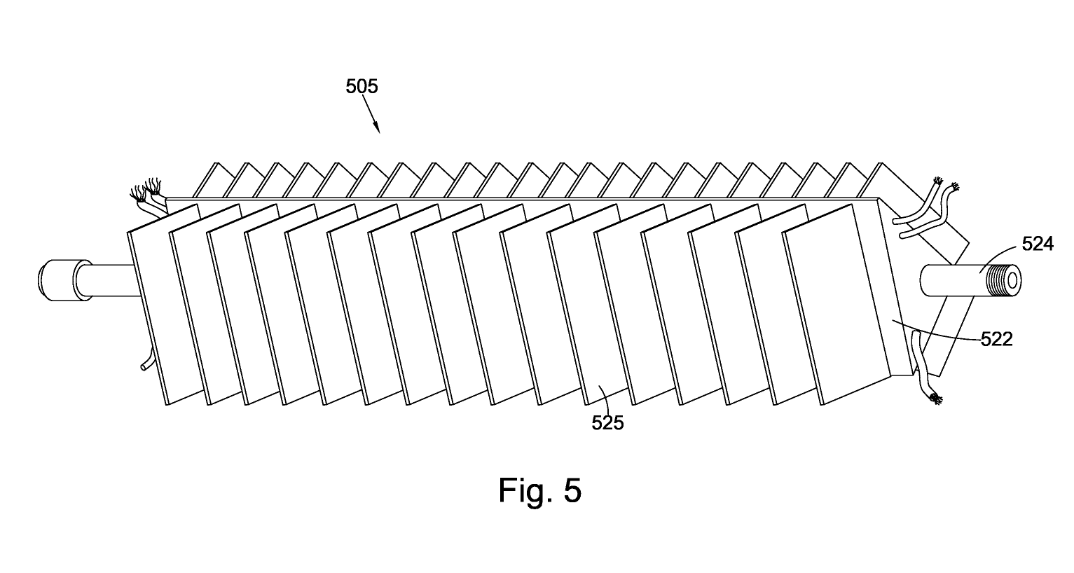

FIGS. 5 and 6 show an embodiment of the thermoelectric generator where three panels are joined together to form a triangular cross sectional area, with FIG. 6 showing a cut away portion and an internal view of the thermoelectric generator. A duct (524) runs through the central axis of the thermoelectric generator and is for conveying heat transfer fluid.

The thermoelectric generator shown in FIGS. 5 and 6 are configured to have an array of fins (525) formed and substantially perpendicular to the outer surface of each panel. These fins increase the surface area of the thermoelectric generator exposed to the water which increases the efficiency of electricity generation via the thermoelectric effect. Ideally an inner duct (524a) is formed and is situated within the outer duct (524b) made up of the panels which interface the water, with the inner and outer duct being separated by thermal interface material (526) for increasing thermal energy transfer between contacted surfaces by decreasing the thermal resistance which occurs as a result of the free space between surfaces. Preferably the outer duct is formed with fins for increasing the surface area exposed to the surrounding water. In the embodiment of the thermoelectric generator shown in FIGS. 5 and 6 the inner and outer ducts have a triangular cross sectional outline.

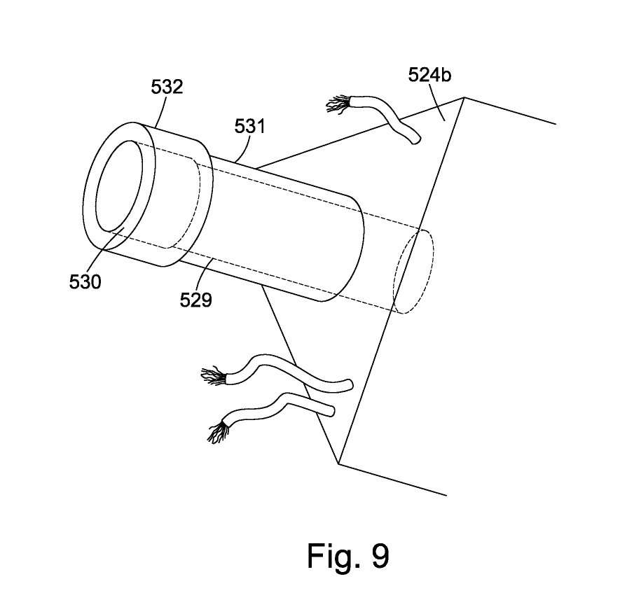

FIG. 6 shows the internal view of a thermoelectric generator which has both inner and outer ducts. A first sheet of thermal electric material (527a), such as pyrolytic graphite material, is placed between the thermoelectric module and the inner duct and a second sheet (527b) is placed between the thermoelectric module and the outer duct. The individual thermoelectric generator modules are connected to each other by electrical wiring (528) which may be connected in series or in parallel. FIG. 10 shows the cross sectional view of the embodiment of the thermoelectric generator shown in FIG. 6.

In operation heat transfer fluid flows through the space formed within the inner duct and comes into contact with the inner facing surface of the inner duct. This causes thermal energy to flow from the heat transfer fluid across the boundaries of the inner duct, thermoelectric module and outer duct and the thermal energy then flows out into the surrounding water. Electrical energy is generated in each of the thermoelectric modules via the thermoelectric effect associated with thermal electric materials as a result of the temperature difference between the heat transfer fluid flowing through the thermoelectric generator and the surrounding water.

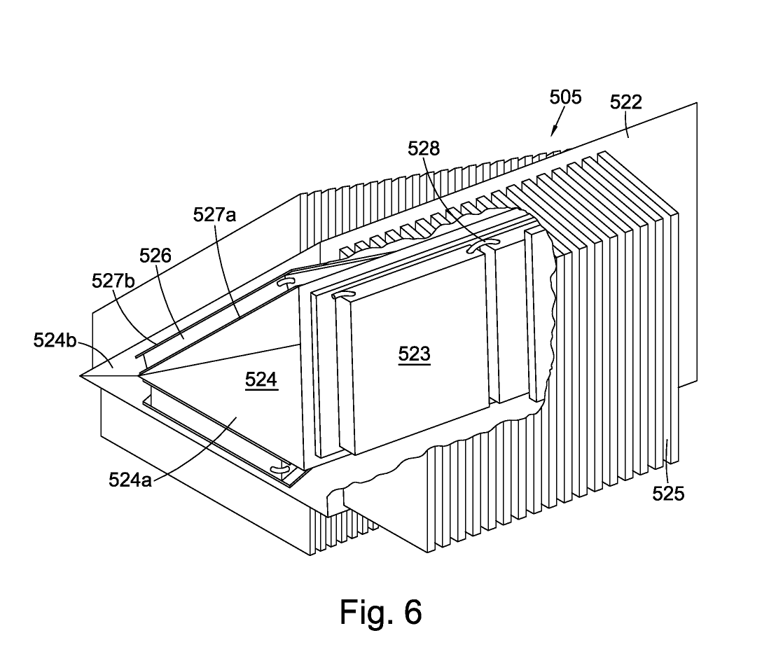

FIG. 7 shows the end view of an inner duct, the embodiment of the inner duct shown in this figure has a triangular cross sectional area. The end part of the inner duct has an outlet tube (529) which is capable of conveying heat transfer fluid. The end region of the outlet tube (i.e. furthest from the end of the inner duct) has an engagement region (530) which is capable of coupling with the engagement region on an outlet tube formed on an end of another inner duct. Preferably the region of the outlet tube between the inner duct and the engagement region are insulated with thermal insulating material to minimise heat loss.

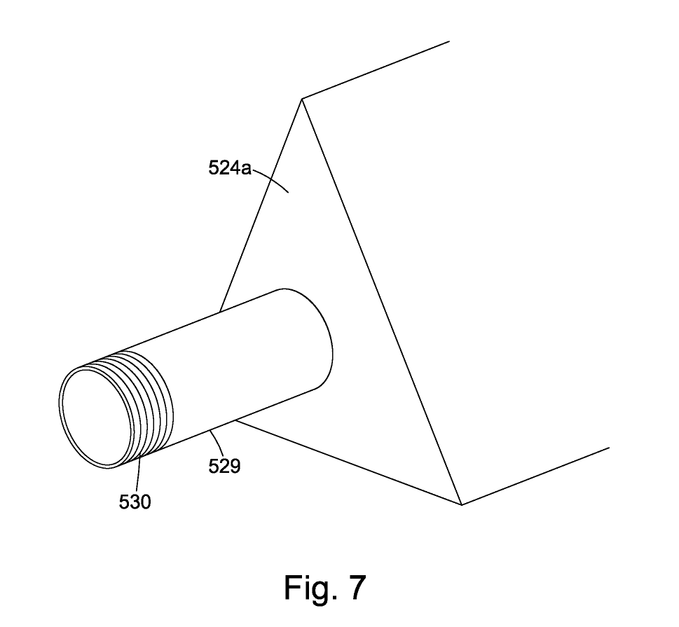

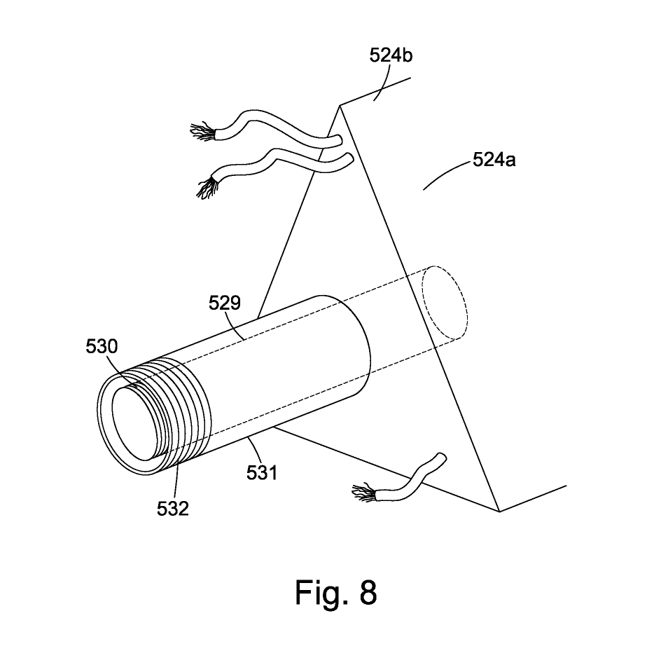

FIGS. 8 and 9 show end views of an outer duct, the embodiment of the outer ducts shown in these figure have triangular cross sectional areas. As with the end parts of the inner ducts, the ends of the outer ducts also have outlet tubes (531) with engagement regions (532) for coupling to the engagement region of the outlet tube of an adjacent outer duct. As the inner duct is positioned within the outer duct, the outlet tube of the inner duct is surrounded by the outlet tube of the corresponding outer duct. One or more additional outlets are formed in the end part of the outer duct for conveying the electrical wiring which connect adjacent thermoelectric modules.

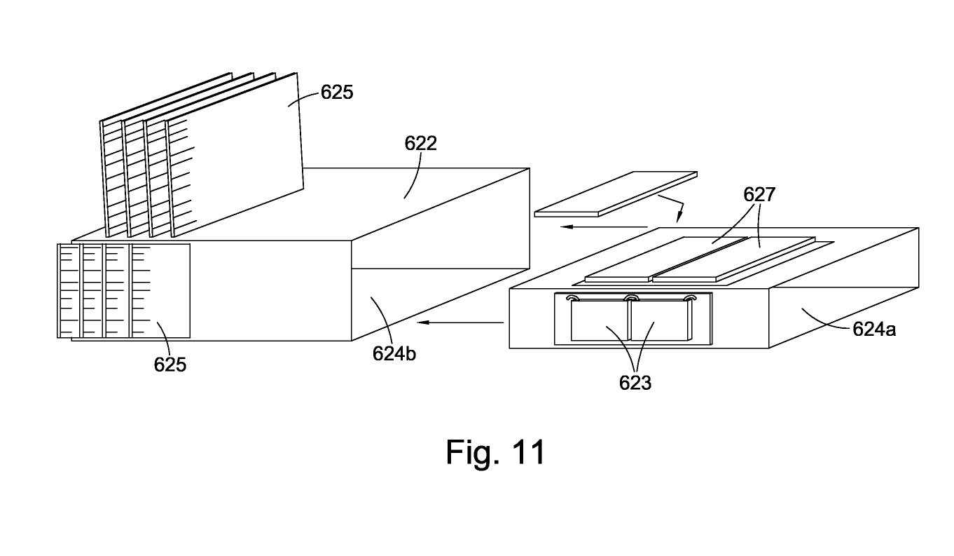

In another embodiments of the thermoelectric generator one or more panels are joined to form a duct with a cross sectional area which is substantially circular. An example of this type of thermoelectric generator is shown in FIG. 12. In the embodiment of the thermoelectric generator shown in FIG. 12, both the inner and outer ducts have a circular cross sectional profile with the inner duct being seen in FIG. 12 through a cut away portion of the outer duct. Similar to other embodiments, an array of fins (725) are formed and substantially perpendicular to the outer surface of the outer duct.

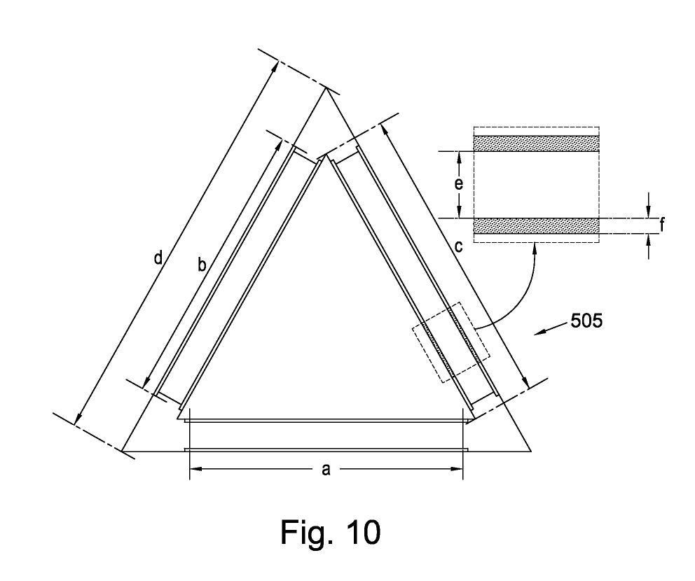

In yet another embodiment of the thermoelectric generator four panels are joined together to form a cross sectional area which is substantially rectangular. An example of this type of thermoelectric generator is shown in FIG. 11. In the embodiment of the thermoelectric generator shown in FIG. 11, both the inner and outer ducts have rectangular cross sectional profiles and are depicted separately in FIG. 11. Similar to other embodiments, an array of fins (625) are formed and substantially perpendicular to the outer surface of the outer duct.

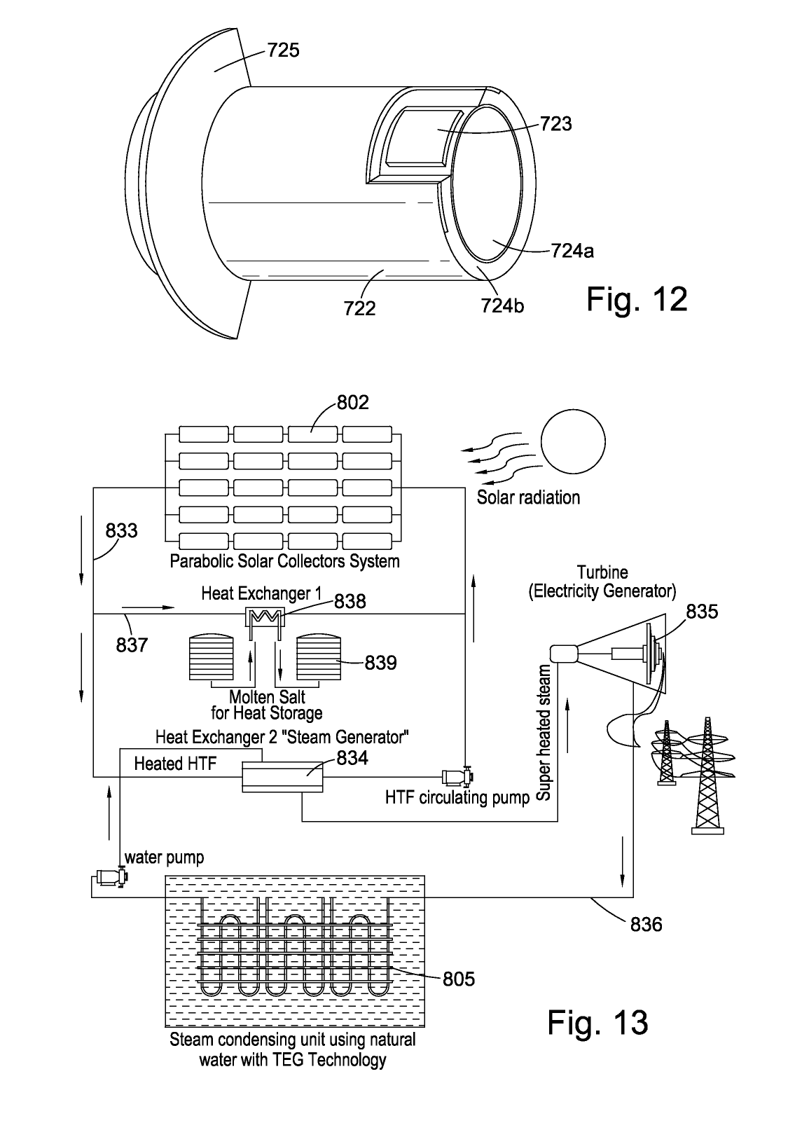

A further embodiment of this invention provides a system for converting thermal energy into electrical energy comprising a solar concentrator for directing sunlight to heat transfer fluid; said heat transfer fluid being for absorbing solar energy from the sunlight and converting the solar energy into thermal energy; a first conveyance (833) for transferring the portion of heat transfer fluid towards a steam generator (834) for heating and converting water from liquid into steam. An additional source of heating may be used together with the heat transfer fluid to heat and convert water from liquid into steam. The additional source may be coal and/or gas combustion and/or other commonly used sources of energy. The system may further comprise a steam driven turbine (835) for generating electrical energy using power from the generated steam; and a second conveyance (836) for recycling the steam back to the steam generator via a thermoelectric generator (805) and a steam condensing unit (805) submerged in water. The thermoelectric generator is for generating electricity based on the temperature difference between the steam and the water surrounding the thermoelectric generator. The steam condensing unit is for condensing the steam into liquid water using water surrounding the steam condensing unit. The thermoelectric generator may be integrated into the steam condensing unit such that the steam is used for electricity generation via the thermoelectric effect and is condensed simultaneously. A schematic of this system is shown in FIG. 13.

Preferably the steam generated in the steam generator is super heated steam. Superheated steam is preferred in this embodiment because it is able to release a large quantity of energy for driving the turbine without the temperature of the steam dropping below the condensation point as is known in the art. The steam conveyed to the thermoelectric generator still retains sufficient thermal energy to permit electricity generation in the thermoelectric generator in addition to that produced by the turbine.

The aspect of the invention shown in FIG. 13 may also include an additional conveyance (837) for transferring a portion of the heat transfer fluid leaving the solar concentrators towards a heat exchanger (838). The heat exchanger is able to extract thermal energy from the heat transfer fluid with that thermal energy being stored in a heat retention medium, preferably that medium is molten salt. As is known in the art molten salt can be used to retain thermal energy captured in solar concentrators during sunlight so that electricity may be generated during periods where light intensity is low, for example during bad weather or at night.

The present invention is not to be limited in scope by the specific aspects and embodiments described herein. Indeed, various modifications of the invention in addition to those described herein will become apparent to those skilled in the art from the foregoing description and accompanying figures. Such modifications are intended to fall within the scope of the appended claims. Moreover, all aspects and embodiments described herein are considered to be broadly applicable and combinable with any and all other consistent aspects and embodiments, as appropriate.

1. A system for converting thermal energy into electrical energy comprising:
a solar concentrator for directing sunlight to a portion of heat transfer fluid;
said portion of heat transfer fluid being for absorbing solar energy from the sunlight and converting the solar energy into thermal energy; and
a conveyance for transferring the portion of heat transfer fluid towards a thermoelectric generator;
the thermoelectric generator is configured to generate electrical energy via the thermoelectric effect;
wherein the system is configured such that the thermoelectric generator is submerged in water and is configured to generate electrical energy based on a temperature difference between the portion of heat transfer fluid and the water.

2. A system as claimed in claim 1, wherein the thermoelectric generator is positioned below the surface of the water it is submerged in and wherein the water is contained in a natural or man-made reservoir.

3. A system as claimed in claim 1, wherein the system further comprises a feedback loop for recycling said portion of heat transfer fluid from the thermoelectric generator back to absorb further solar energy from sunlight directed by the solar concentrator.

4. A system as claimed in claim 3, wherein the feedback loop comprises a storage tank.

5. A system as claimed in claim 1, wherein the solar concentrator is located on shore.

6. A system as claimed in claim 1, wherein the solar concentrator is located off shore.

7. A system as claimed in claim 1, wherein the system is located on an artificial island buoyant on the surface of the water.

8. A system as claimed in claim 7, wherein the artificial island is capable of rotating to a direction according to the sun's position to maximise the amount of solar radiation captured by the solar concentrators.

9. A system as claimed in claim 1, wherein the thermoelectric generator comprises one or more panels arranged to be joined together such that the outer facing surfaces of the one or more panels incorporate one or more thermoelectric modules which interface the water and the inner facing surfaces form a duct for conveying heat transfer fluid received from the conveyance.

10. A system as claimed in claim 9, wherein one or more panels are joined to form a duct with a cross-sectional area which is substantially circular, triangular or rectangular.

11. A system as claimed in claim 9, wherein an array of fins are formed on and substantially perpendicular to the outer surface of each panel.

12. A system as claimed in claim 1, wherein the solar concentrator is configured to automatically alter its orientation according to the position of the sun at that time of day to maximise the amount of sunlight being directed to the heat transfer fluid at that time of day.

13. A system for converting thermal energy into electrical energy comprising:
a solar concentrator for directing sunlight to a portion of heat transfer fluid;
said portion of heat transfer fluid being for absorbing solar energy from the sunlight and converting the solar energy into thermal energy;
a first conveyance for transferring the portion of heat transfer fluid towards a steam generator for converting water into steam; and
a second conveyance for conveying the steam to a thermoelectric generator for converting thermal energy into electrical energy by the thermoelectric effect;
wherein the thermoelectric generator is submerged in water and is configured to generate electrical energy based on a temperature difference between the steam and the surrounding water.

14. A system as claimed in claim 13, wherein the second conveyance is configured to recycle the steam back to the steam generator via a condensation unit for condensing the steam into water.

15. A system as claimed in claim 13, further comprising a steam driven turbine for generating electrical energy using the generated steam.

16. A system as claimed in claim 13, further comprising a third conveyance for conveying the heat transfer fluid to a heat exchanger for storing heat from the heat transfer fluid using molten salt.

17. A method of converting thermal energy into electrical energy said method comprising:
directing sunlight, by a solar concentrator, to a portion of heat transfer fluid;
converting, by the heat transfer fluid, solar energy absorbed from the sunlight to thermal energy;
conveying the portion of heat transfer fluid; and
converting, by the thermoelectric generator, thermal energy into electrical energy via the thermoelectric effect;
wherein the method further comprises submerging the thermoelectric generator in water, and wherein said electrical energy is generated based on a temperature difference between the portion of heat transfer fluid and the water or based on a temperature difference between steam and the surrounding water, wherein the steam is generated by water heated by the heat transfer fluid.

18. A method according to claim 17, said method further comprising recycling the portion of heat transfer fluid from the thermoelectric generator back to absorb further solar energy directed by the solar concentrator.

19. A method according to claim 17, further comprising adjusting the orientation of the solar concentrator such that the amount of sunlight being reflected is optimised for the position of the sun at that time of day.

20. A method according to claim 17, said method comprising conveying the portion of heat transfer fluid through one or more additional solar concentrators before conveying it towards the thermoelectric generator.
